(19) United States
(12) Patent Application Publication
(10) Pub. No.: US 2025/0384918 A1
(43) Pub. Date: Dec. 18, 2025

(54) SEMICONDUCTOR DEVICE EXECUTING MAC OPERATION

(71) Applicant: SK hynix Inc., Icheon-si Gyeonggi-do (KR)

(72) Inventor: Min Su PARK, Icheon-si Gyeonggi-do (KR)

(73) Assignee: SK hynix Inc., Icheon-si Gyeonggi-do (KR)

(21) Appl. No.: 18/957,232

(22) Filed: Nov. 22, 2024

(30) Foreign Application Priority Data
Jun. 17, 2024 (KR) 10-2024-0078539

(51) Int. Cl. G11C 11/4091; G06F 7/544; G11C 11/408; G11C 11/4094

(52) U.S. Cl. CPC G11C 11/4091; G06F 7/5443; G11C 11/4085; G11C 11/4094

(57) ABSTRACT

A semiconductor device includes a sense amplifier circuit including a plurality of sense amplifiers connected to a plurality of columns, wherein the plurality of sense amplifiers stores internal data output by the plurality of columns by amplifying the internal data, and generates an internal voltage by driving a segment line based on the internal data and a plurality of column signals after the start of an arithmetic operation, and an arithmetic circuit configured to generate weight data by performing a multiply-accumulate (MAC) operation based on a voltage level of the internal voltage and configured to output the weight data to the segment line.

### CROSS-REFERENCE TO RELATED APPLICATION

The present application claims priority under 35 U.S.C. § 119(a) to Korean Patent Application No. 10-2024-0078539, filed in the Korean Intellectual Property Office on Jun. 17, 2024, the entire contents of which application is incorporated herein by reference.

### BACKGROUND

### 1. Technical Field

The present disclosure relates to a semiconductor device that executes a multiply-accumulate (MAC) operation.

### 2. Related Art

A semiconductor memory device is characterized as one of a volatile memory device and a nonvolatile memory device. Dynamic Random Access Memory (DRAM) is widely used as main memory of a system because DRAM has a quick response time and a fast operation speed. Common DRAM writes data or outputs data that are written in the DRAM under the control of a host. A memory device configured to perform an arithmetic operation that is performed outside the memory device within the memory device is a recent development. A memory device within which an arithmetic device is integrated is referred to as an arithmetic-in-memory (AIM) device, a computing-in-memory (CIM) device, or a process-in-memory (PIM) device. The AIM device, the CIM device, and the PIM device can improve overall performance relating to an arithmetic operation because the AIM device, the CIM device, and the PIM device directly perform arithmetic operations within the memory device.

As technology for manufacturing a semiconductor device develops, a packaging technology for a plurality of memory devices for the semiconductor device achieves high integration and high performance. Packaging technologies for semiconductor devices are developing in various ways. Three-dimensional structure include a plurality of memory devices vertically stacked, whereas two-dimensional structures include a plurality of memory devices arranged in a direction horizontal to a substrate or printed circuit board (PCB). A semiconductor device including a three-dimensional structure may be implemented by stacking a plurality of memory devices utilizing through silicon vias (TSV) or by stacking a plurality of memory devices utilizing hybrid bonding, such as high bandwidth memory (HBM).

### SUMMARY

In an embodiment, a semiconductor device may include a sense amplifier circuit including a plurality of sense amplifiers connected to a plurality of columns, wherein the plurality of sense amplifiers stores internal data output by the plurality of columns by amplifying the internal data and generates an internal voltage by driving a segment line based on the internal data and a plurality of column signals after the start of an arithmetic operation, and an arithmetic circuit configured to generate weight data by performing a multiply-accumulate (MAC) operation based on a voltage level of the internal voltage and configured to output the weight data to the segment line.

In an embodiment, a semiconductor device may include a memory control circuit configured to generate a plurality of row addresses and a plurality of column addresses after the start of an active operation, and a memory circuit configured to output internal data from one of a plurality of columns based on the plurality of row addresses and the plurality of column addresses after the start of the active operation, configured to generate weight data by performing a multiply-accumulate (MAC) operation based on a plurality of input data and the internal data after the start of an arithmetic operation, and configured to store the weight data as the internal data.

In an embodiment, a semiconductor device may include a memory control circuit configured to generate a plurality of row addresses and a plurality of column addresses after the start of an active operation, and a memory circuit configured to activate one of a plurality of word lines based on the plurality of row addresses and the plurality of column addresses after the start of the active operation, configured to output internal data from a memory cell that is connected to the activated word line, configured to deactivate the plurality of word lines after the start of an arithmetic operation, and configured to perform a multiply-accumulate (MAC) operation based on a plurality of input data and the internal data.

In an embodiment, a semiconductor device may include a memory control circuit configured to generate a plurality of row addresses and a plurality of column addresses; and a memory circuit comprising a memory cell and a plurality of word lines including a first word line connected to the memory cell and configured to activate the first word line based on the plurality of row addresses and the plurality of column addresses and output internal data from the memory cell, configured to deactivate the plurality of word lines subsequent to beginning an arithmetic operation, and further comprising a multiply-accumulate (MAC) operator that performs a MAC operation based on input data and the internal data.

### BRIEF DESCRIPTION OF THE DRAWINGS

FIG. 1 is a block diagram illustrating a semiconductor device according to an embodiment of the present disclosure.

FIG. 2 and FIG. 3 are tables including data during operation of a command generation circuit according to an embodiment of the present disclosure.

FIG. 4 is a block diagram illustrating an embodiment of a first mat included in a semiconductor device according to an embodiment of the present disclosure.

FIG. 5 is a block diagram illustrating a column control circuit included in a first mat according to an embodiment of the present disclosure.

FIG. 6 is a block diagram illustrating an arithmetic circuit included in a first mat according to an embodiment of the present disclosure.

FIG. 7 is a block diagram illustrating an embodiment of a MAC operator according to an embodiment of the present disclosure.

FIG. 8 is a timing diagram during an arithmetic operation of a semiconductor device according to an embodiment of the present disclosure.

FIG. 9 to FIG. 12 are block diagrams illustrating a memory circuit according to an embodiment of the present disclosure.

FIG. 13 is a block diagram illustrating a semiconductor device according to an embodiment of the present disclosure.

FIG. 14 is a diagram illustrating an embodiment of a stack memory system according to an embodiment of the present disclosure.

### DETAILED DESCRIPTION

The cross-hatching throughout the figures illustrates corresponding or similar areas between the figures rather than indicating the materials associated with the areas.

Terms such as “first” and “second” are used to distinguish between various components and do not imply size, order, priority, quantity, or importance of the components. For example, a first component may be referred to as a second component in one example, and the second component may be referred to as a first component in another example. Terms such as “vertical,” “below,” “under,” “over,” “on,” “side,” “high,” “low,” “left,” “right,” “column,” “row,” “level,” and other terms implying relative spatial relationship or orientation are utilized only for the purpose of ease of description or reference to a drawing and are not otherwise limiting.

When one element is identified as “connected” to another element, the elements may be connected directly or through an intervening element between the elements. When two elements are identified as “directly connected,” one element is directly connected to the other element without an intervening element between the two elements.

A “logic high level” and a “logic low level” are used to describe the logic levels of signals. A signal having a “logic high level” is distinguished from a signal having a “logic low level.” For example, when a signal having a first voltage corresponds to a signal having a “logic high level,” a signal having a second voltage corresponds to a signal having a “logic low level.” According to an embodiment, a “logic high level” is at a voltage higher than a “logic low level.” According to an embodiment, the logic levels of signals may be at different logic levels or opposite logic levels. For example, a signal having a logic high level may be at a logic low level in some embodiments, and a signal having a logic low level may be at a logic high level in other embodiments.

Embodiments of the the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

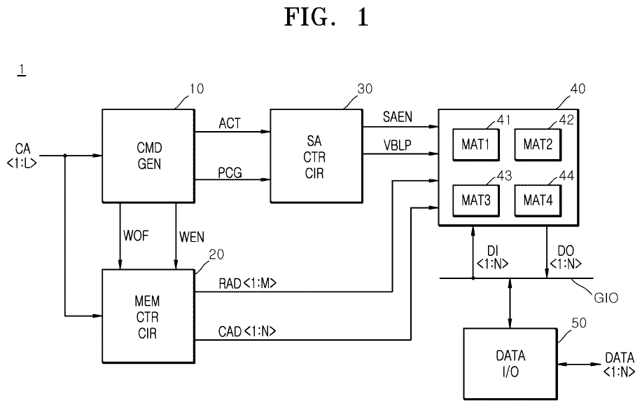

As illustrated in FIG. 1, the semiconductor device 1 according to an embodiment of the present disclosure includes a command generation circuit (CMD GEN) 10, a memory control circuit (MEM CTR CIR) 20, a sense amplifier control circuit (SA CTR CIR) 30, a memory circuit 40, and a data input and output (I/O) circuit (DATA I/O) 50.

The command generation circuit 10 generates an active command ACT, a word line deactivation command WOF, a word line activation command WEN, and a pre-charge command PCG based on first to L-th command addresses CA<1:L>, where L is a positive integer.

After the start of an arithmetic operation, the command generation circuit 10 generates the active command ACT, the word line deactivation command WOF, the word line activation command WEN, and the pre-charge command PCG that are sequentially enabled by decoding the first to L-th command addresses CA<1:L>. After the start of normal operation, the command generation circuit 10 generates the active command ACT and the pre-charge command PCG that are sequentially enabled by decoding the first to L-th command addresses CA<1:L>.

The memory control circuit 20 generates first to M-th row addresses RAD<1:M>and first to N-th column addresses CAD<1:N>, based on the first to L-th command addresses CA<1:L>, where M and N are positive integers. The memory control circuit 20 generates the first to M-th row addresses RAD<1:M> based on a subset of bits of the first to L-th command addresses CA<1:L>. The memory control circuit 20 generates the first to N-th column addresses CAD<1:N> based on a subset of bits of the first to L-th command addresses CA<1:L>. The memory control circuit 20 generates the first to M-th row addresses RAD<1:M>, each of which are disabled when the word line deactivation command WOF is enabled. The memory control circuit 20 generates the first to M-th row addresses RAD<1:M> based on a subset of bits of the first to L-th command addresses CA<1:L> when the word line activation command WEN is enabled.

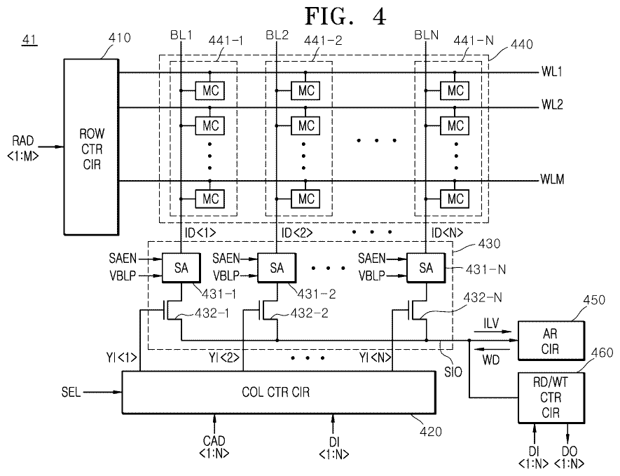

The sense amplifier control circuit 30 generates a sense amplifier enable signal SAEN and a pre-charge voltage VBLP based on the active command ACT and the pre-charge command PCG. When the active command ACT is enabled, the sense amplifier control circuit 30 generates the sense amplifier enable signal SAEN enabled to activate a plurality of sense amplifiers, for example, 431-1 to 431-N in FIG. 4. When the pre-charge command PCG is enabled, the sense amplifier control circuit 30 generates the pre-charge voltage VBLP at a voltage level that pre-charges a plurality of bit lines, for example, BL1 to BLN in FIG. 4.

In an embodiment, the memory circuit 40 includes a first mat MAT1) 41, a second mat (MAT2) 42, a third mat (MAT3) 43, and a fourth mat (MAT4) 44.

The first mat 41 outputs one internal datum, among first to N-th internal data, for example, ID<1:N> in FIG. 4, generated based on the first to M-th row addresses RAD<1:M> and the first to N-th column addresses CAD<1:N>, as first to N-th output data DO<1:N>, by amplifying the one internal datum when the sense amplifier enable signal SAEN is enabled after the start of a read operation during normal operation. The first mat 41 outputs first to N-th internal data, for example, ID<1:N> in FIG. 4, as the first to N-th output data DO<1:N> through a global line GIO after the start of a read operation during normal operation. The first mat 41 stores the first to N-th input data DI<1:N> that are input through the global line GIO as the first to N-th internal data, for example, ID<1:N> in FIG. 4, based on the first to M-th row addresses RAD<1:M> and the first to N-th column addresses CAD<1:N> when the sense amplifier enable signal SAEN is enabled after the start of a write operation during normal operation. The first mat 41 drives each of the plurality of bit lines, for example, BL1 to BLN in FIG. 4, to the voltage level of the pre-charge voltage VBLP after the start of a pre-charge operation during normal operation. Normal operation includes a read operation and a write operation that input and output data in a common semiconductor device. Normal operation includes a pre-charge operation that drives each of the plurality of bit lines to the voltage level of the pre-charge voltage VBLP in a common semiconductor device.

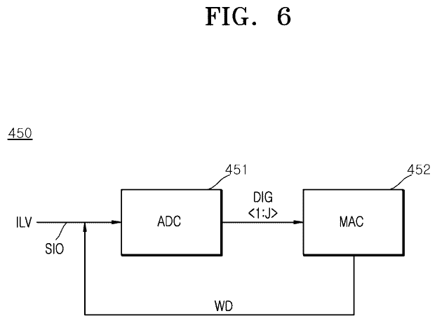

The first mat 41 stores one internal datum, among the first to N-th internal data, for example, ID<1:N> in FIG. 4, generated based on the first to M-th row addresses RAD<1:M> and the first to N-th column addresses CAD<1:N>, by amplifying the one internal datum when the sense amplifier enable signal SAEN is enabled after the start of an arithmetic operation. N and M are positive integers. The first mat 41 drives a segment line, for example, SIO in FIG. 6 by activating the plurality of sense amplifiers based on one of the first to N-th internal data, for example, ID<1:N> in FIG. 4, stored after the start of an arithmetic operation, and the first to N-th column addresses CAD<1:N> or the first to N-th input data DI<1:N>. The first mat 41 generates an internal voltage having a varying voltage level, for example, ILV in FIG. 4, by driving the segment line, for example, SIO in FIG. 4, after the start of an arithmetic operation. The first mat 41 generates weight data, for example, WD in FIG. 4 by performing an arithmetic operation based on the voltage level of the internal voltage, for example, ILV in FIG. 4, after the start of an arithmetic operation. The first mat 41 stores the weight data, for example, WD in FIG. 4 as the first to N-th internal data, for example, ID<1:N> in FIG. 4, based on the first to M-th row addresses RAD<1:M> and the first to N-th column addresses CAD<1:N> after the start of an arithmetic operation. The arithmetic operation may be an arithmetic operation such as used in an artificial intelligence (A/I) device and a machine learning (M/L) device. The arithmetic operation may be a MAC operation that performs a multiplication operation and an addition operation on weight data and input data.

The second mat 42, the third mat 43, and the fourth mat 44 are implemented using similar circuits as the first mat 41 and perform similar operations as the first mat 41, except that the second mat 42, the third mat 43, and the fourth mat 44 are selectively activated based on the first to M-th row addresses RAD<1:M> and the first to N-th column addresses CAD<1:N>.

The memory circuit 40 includes the first mat 41, the second mat 42, the third mat 43, and the fourth mat 44, but may include a different quantity of mats. The mat may be implemented with a common memory cell array including a plurality of memory cells.

The data I/O circuit 50 generates first to N-th data DATA<1:N> based on the first to N-th output data DO<1:N> loaded onto the global line GIO after the start of a read operation during normal operation. The data I/O circuit 50 outputs the first to N-th data DATA<1:N> to a controller (not illustrated) or other external device after the start of a read operation during normal operation.

The data I/O circuit 50 generates the first to N-th input data DI<1:N> based on the first to N-th data DATA<1:N> input from the controller (not illustrated) or other external device after the start of a write operation during normal operation. The data I/O circuit 50 outputs the first to N-th input data DI<1:N > to the global line GIO after the start of a write operation during normal operation.

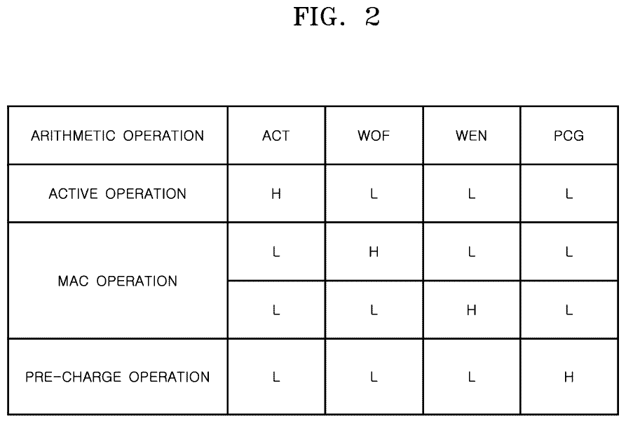

Operation of the command generation circuit 10 after the start of an arithmetic operation according to an embodiment of the present disclosure is described with reference to FIG. 2.

The command generation circuit 10 generates the active command ACT enabled at a logic high level H to perform an active operation by decoding the first to L-th command addresses CA<1:L> after the start of an arithmetic operation.

After generating the active command ACT, the command generation circuit 10 generates the word line deactivation command WOF enabled at a logic high level H to perform a MAC operation by decoding the first to L-th command addresses CA<1:L> after the start of the arithmetic operation.

After generating the word line deactivation command WOF, the command generation circuit 10 generates the word line activation command WEN enabled at a logic high level H to perform the MAC operation by decoding the first to L-th command addresses CA<1:L> after the start of the arithmetic operation.

After generating the word line deactivation command WOF, the command generation circuit 10 generates the pre-charge command PCG enabled at a logic high level H to perform a pre-charge operation by decoding the first to L-th command addresses CA<1:L> after the start of the arithmetic operation.

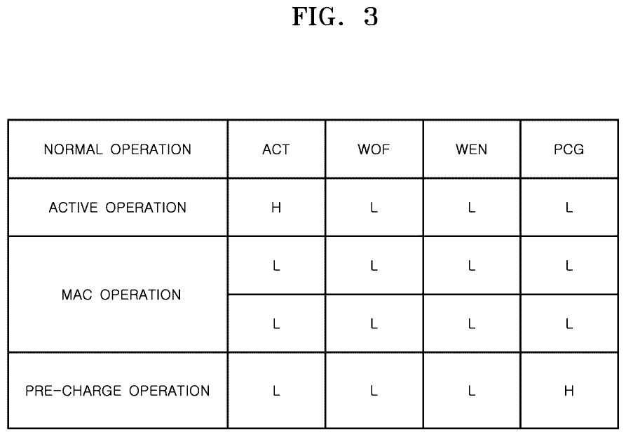

Operation of the command generation circuit after start of normal operation according to an embodiment of the present disclosure is described with reference to FIG. 3.

The command generation circuit 10 generates the active command ACT enabled at a logic high level H to perform an active operation by decoding the first to L-th command addresses CA<1:L> after the start of normal operation.

The command generation circuit 10 generates the word line deactivation command WOF disabled at a logic low level L to block or prevent performing a MAC operation after the start of normal operation.

The command generation circuit 10 generates the word line deactivation command WOF disabled at a logic low level L to block or prevent performing a MAC operation after the start of normal operation.

After generating the active command ACT, the command generation circuit 10 generates the pre-charge command PCG enabled at a logic high level H to perform a pre-charge operation by decoding the first to L-th command addresses CA<1:L> after the start of normal operation.

FIG. 4 is a block diagram illustrating an embodiment of the first mat 41 included, for example, in the memory circuit 40. The first mat 41 includes a row control circuit (ROW CTR CIR) 410, a column control circuit (COL CTR CIR) 420, a sense amplifier circuit 430, a memory cell array 440, an arithmetic circuit (AR CIR) 450, and a read write control circuit 460 (RD/WT CTR CIR).

The row control circuit 410 activates the first word line WL1 to the M-th word line WLM based on the first to M-th row addresses RAD<1:M>. The row control circuit 410 activates one of the word lines WL1 to WLM based on the first to M-th row addresses RAD<1:M> after the start of an active operation during normal operation. The row control circuit 410 activates one of the word lines WL1 to WLM based on the first to M-th row addresses RAD<1:M> after the start of an active operation during an arithmetic operation.

The column control circuit 420 generate first to N-th column signals YI<1:N> from one of the first to N-th column addresses CAD<1:N> and the first to N-th input data DI<1:N>. The column control circuit 420 generates the first to N-th column signals YI<1:N> based on the first to N-th column addresses CAD<1:N> when a selection signal SEL is disabled after the start of normal operation. The column control circuit 420 generates the first to N-th column signals YI<1:N> based on the first to N-th input data DI<1:N> when the selection signal SEL is enabled after the start of an arithmetic operation.

In an embodiment, the sense amplifier circuit 430 includes the plurality of sense amplifiers (SA) 431-1 to 431-N and a plurality of switches 432-1 to 432-N.

The first sense amplifier 431-1 is disposed between the first bit line BL1 and the first switch 432-1. The first sense amplifier 431-1 amplifies the first internal data ID<1> when the sense amplifier enable signal SAEN is enabled at a logic high level. The first sense amplifier 431-1 stores the first internal data ID<1> that are amplified when the sense amplifier enable signal SAEN is enabled at a logic high level. The first sense amplifier 431-1 generates the first internal data ID<1> by amplifying the first input data DI<1> loaded onto a segment line SIO when the first column signal YI<1> is enabled at a logic high level and the first switch 432-1 is turned on. The first sense amplifier 431-1 drives the first bit line BL1 to the voltage level of the pre-charge voltage VBLP after the start of a pre-charge operation during normal operation and an arithmetic operation.

The first switch 432-1 is disposed between the first sense amplifier 431-1 and the segment line SIO. The first switch 432-1 is turned on when the first column signal YI<1> is enabled at a logic high level. The first switch 432-1 connects the first sense amplifier 431-1 and the segment line SIO when the first column signal YI<1 > is enabled at a logic high level. The first switch 432-1 may be implemented with an NMOS transistor.

The first sense amplifier 431-1 and the first switch 432-1 drives the segment line SIO when the first column signal YI<1> is enabled at a logic high level.

The second sense amplifier 431-2 is disposed between the second bit line BL2 and the second switch 432-2. The second sense amplifier 431-2 amplifies the second internal data ID<2> when the sense amplifier enable signal SAEN is enabled at a logic high level. The second sense amplifier 431-2 stores the second internal data ID<2> that are amplified when the sense amplifier enable signal SAEN is enabled at a logic high level. The second sense amplifier 431-2 generates the second internal data ID<2> by amplifying the second input data DI<2> loaded onto the segment line SIO when the second column signal YI<2> is enabled at a logic high level and the second switch 432-2 is turned on. The second sense amplifier 431-2 drives the second bit line BL2 to the voltage level of the pre-charge voltage VBLP after the start of a pre-charge operation during normal operation and an arithmetic operation.

The second switch 432-2 is disposed between the second sense amplifier 431-2 and the segment line SIO. The second switch 432-2 is turned on when the second column signal YI<2> is enabled at a logic high level. The second switch 432-2 connects the second sense amplifier 431-2 and the segment line SIO when the second column signal YI<2> is enabled at a logic high level. The second switch 432-2 may be implemented with an NMOS transistor.

The second sense amplifier 431-2 and the second switch 432-2 drive the segment line SIO when the second column signal YI<2> is enabled at a logic high level.

The third sense amplifier 431-3 to the N-th sense amplifier 431-N are implemented using similar circuits as the sense amplifiers 431-1 and 431-2 and perform similar operations as the sense amplifiers 431-1 and 431-2, except that input and output connections for the sense amplifiers 431-3 to 431-N are different from input and output connections for the sense amplifiers 431-1 and 431-2.

The third to N-th switches 432-3 to 432-N are implemented using similar circuits as the switches 432-1 and 432-2 and perform similar operations as the switches 432-1 and 432-2, except that connection relations in the switches 432-3 to 432-N are different from connection relations in the switches 432-1 and 432-2.

The sense amplifier circuit 430 stores one internal datum, among the first to N-th internal data ID<1:N>, by amplifying the one internal datum after the start of an arithmetic operation. The sense amplifier circuit 430 generates the internal voltage ILV by driving the segment line SIO based on the quantity of sense amplifiers 431-1 to 431-N that are activated based on the first to N-th column signals YI<1:N>. The sense amplifier circuit 430 generates the internal voltage ILV at an increased voltage level when the quantity of sense amplifiers 431-1 to 431-N that are activated based on the first to N-th column signals YI<1:N> is increased. The sense amplifier circuit 430 generates the internal voltage ILV at a decreased voltage level when the quantity of sense amplifiers 431-1 to 431-N that are activated based on the first to N-th column signals YI<1:N> is decreased.

In an embodiment, the memory cell array 440 includes a first column 441-1 to an N-th column 441-N.

In an embodiment, the first column 441-1 includes a plurality of memory cells MC connected between the word lines WL1 to WLM and the first bit line BL1. The first column 441-1 outputs, to the first bit line BL1, the first internal data ID<1> stored in the memory cell MC connected to a word line that is activated among the word lines WL1 to WLM. The first column 441-1 stores the first internal data ID<1> in the memory cell MC connected to a word line that is activated among the word lines WL1 to WLM.

The second column 441-2 includes a plurality of memory cells MC connected between the word lines WL1 to WLM and the second bit line BL2. The second column 441-2 output the second internal data ID<2> stored in the memory cell MC that is connected to a word line that is activated, among the first to M-th word lines WL1 to WLM, to the second bit line BL2. The second column 441-2 may store the second internal data ID<2> in the memory cell MC that is connected to a word line that is activated, among the first to M-th word lines WL1 to WLM.

The columns 441-3 to 441-N are implemented using similar circuits as the columns 441-1 and 441-2 and perform similar operations as the columns 441-1 and 441-2, except that connection relations in the columns 441-3 to 441-N are different from the connection relations in the columns 441-1 and 441-2. The plurality of memory cells MC that are included in the columns 441-1 to 441-N may be implemented with volatile memory cells.

The arithmetic circuit 450 is connected to the segment line SIO. The arithmetic circuit 450 performs a MAC operation based on the voltage level of the internal voltage ILV. The arithmetic circuit 450 generates the weight data WD by performing a MAC operation on the internal voltage ILV. After performing the MAC operation, the arithmetic circuit 450 outputs the weight data WD on the segment line SIO.

The read write control circuit 460 is connected to the segment line SIO. The read write control circuit 460 outputs, as the first to N-th output data DO<1:N>, the first to N-th internal data ID<1:N> loaded onto the segment line SIO after the start of a read operation during normal operation. The read write control circuit 460 outputs the first to N-th input data DI<1:N> to the segment line SIO after the start of a write operation during normal operation.

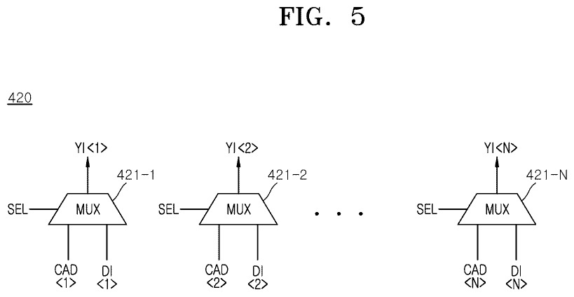

FIG. 5 is a block diagram illustrating an embodiment of the column control circuit 420 included, for example, in the first mat 41. The column control circuit 420 includes a first multiplexer (MUX) 421-1 to an N-th multiplexer MUX 421-N.

The first multiplexer 421-1 outputs the first column address CAD<1> as the first column signal YI<1> when the selection signal SEL is disabled at a logic low level. The first multiplexer 421-1 outputs the first input data DI<1> as the first column signal YI<1> when the selection signal SEL is enabled at a logic high level.

The second multiplexer 421-2 outputs the second column address CAD<2> as the second column signal YI<2> when the selection signal SEL is disabled at a logic low level. The second multiplexer 421-2 outputs the second input data DI<2> as the second column signal YI<2> when the selection signal SEL is enabled at a logic high level.

The third multiplexers 421-3 to the N-th multiplexer 421-N perform similar operations as performed by the multiplexers 421-1 and 421-2 except that the input and output signals for the multiplexers 421-3 to 421-N are different from the input and output signals for the multiplexers 421-1 and 421-2.

FIG. 6 is a block diagram illustrating an embodiment of the arithmetic circuit 450 included, for example, in the first mat 41. The arithmetic circuit 450 includes an analog to digital converter (ADC) 451 and a MAC operator (MAC) 452.

The analog to digital converter 451 generates first to J-th digital signals DIG<1:J> based on the voltage level of the internal voltage ILV. The analog to digital converter 451 generates the first to J-th digital signals DIG<1:J> that are incremented in value as the voltage level of the internal voltage ILV is increased. The analog to digital converter 451 generates the first to J-th digital signals DIG<1:J> that are decremented in value as the voltage level of the internal voltage ILV is decreased. The analog to digital converter 451 may be implemented with a common analog to digital converter (ADC) that generates digital signals at various logic level combinations based on the voltage level of an analog input voltage.

The MAC operator 452 generates the weight data WD based on the first to J-th digital signals DIG<1:J>. The MAC operator 452 generate the weight data WD by performing a MAC operation on the first to J-th digital signals DIG<1:J>. After performing the MAC operation, the MAC operator 452 outputs the weight data WD to the segment line SIO. The MAC operator 452 may be implemented with a MAC operator that performs a multiplication operation and an addition operation on the weight data and the input data, for example, in an A/I device or an M/L device.

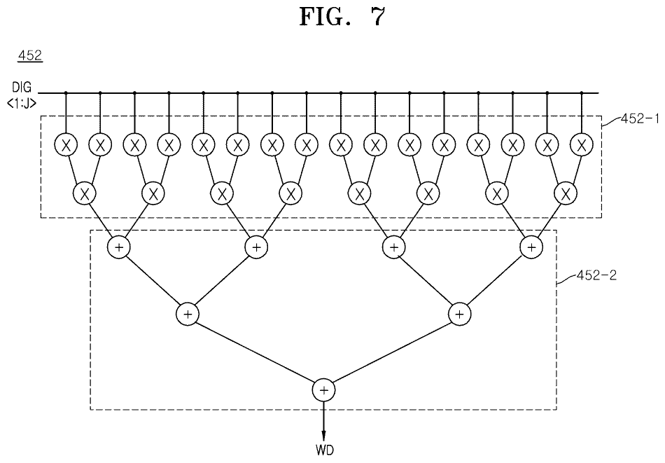

FIG. 7 is a block diagram illustrating an embodiment of the MAC operator 452 included, for example, in the arithmetic circuit 450. The MAC operator 452 includes a multiplier 452-1 and an adder 452-2.

The multiplier 452-1 is implemented with a plurality of multiplication operators “×”. The multiplier 452-1 performs a multiplication operation on the first to J-th digital signals DIG<1:J>. The multiplier 452-1 may be implemented with the plurality of multiplication operators “×” utilizing a tree structure.

The adder 452-2 may be implemented with a plurality of addition operators “+”. The adder 452-2 performs an addition operation on the results of a multiplication operation for the first to J-th digital signals DIG<1:J> in the multiplier 452-1. The adder 452-2 may be implemented with a plurality of addition operator “+” using a tree structure.

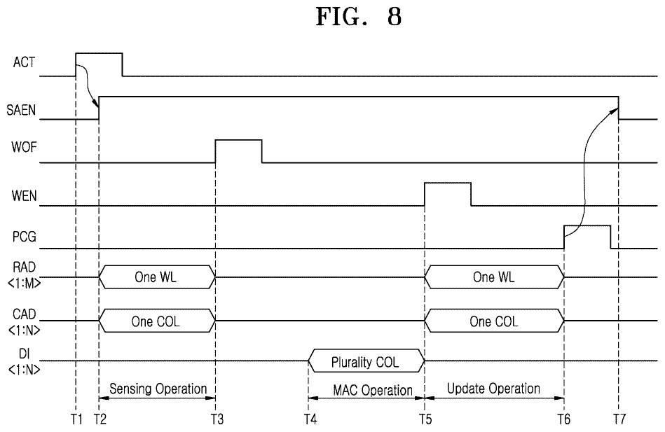

FIG. 8 is a timing diagram during an arithmetic operation of the semiconductor device 1 according to an embodiment of the present disclosure. The arithmetic operation is described with reference to FIG. 8. An arithmetic operation for the first mat 41 is described as an example.

At time T1, the command generation circuit 10 generates the active command ACT enabled at a logic high level by decoding the first to L-th command addresses CA<1:L> after the start of an arithmetic operation.

At time T2, the memory control circuit 20 generates the first to M-th row addresses RAD<1:M> and the first to N-th column addresses CAD<1:N> based on the first to L-th command addresses CA<1:L>. In this example, the first to M-th row addresses RAD<1:M> are generated to have a logic level combination that activates one word line (One WL) among the word lines WL1 to WLM. The first to N-th column addresses CAD<1:N> are generated to have a logic level combination that activates one column (One COL) among the first to N-th columns 441-1 to 441-N.

The sense amplifier control circuit 30 generates the sense amplifier enable signal SAEN enabled at a logic high level to activate the plurality of sense amplifiers 431-1 to 431-N in response to enabling the active command ACT.

The row control circuit 410 of the first mat 41 activates one of the first to M-th word lines WL1 to WLM based on the first to M-th row addresses RAD<1:M> after the start of an active operation during the arithmetic operation.

The column control circuit 420 generates the first to N-th column signals YI<1:N> from the first to N-th column addresses CAD<1:M>.

The sense amplifier circuit 430 amplifies and stores one of the first to N-th internal data ID<1:N> through one of the first to N-th sense amplifiers 431-1 to 431-N activated based on the first to N-th column signals YI<1:N>.

The time period from time T2 to time T3 is a sensing operation interval (Sensing Operation) during which the sense amplifier circuit 430 amplifies one of the first to N-th internal data ID<1:N> after the start of the active operation during the arithmetic operation.

At time T3, the command generation circuit 10 generates the word line deactivation command WOF enabled at a logic high level by decoding the first to L-th command addresses CA<1:L> after the start of the arithmetic operation.

The memory control circuit 20 generates the first to M-th row addresses RAD<1:M>, each of which are disabled when the word line deactivation command WOF is enabled.

The row control circuit 410 of the first mat 41 deactivates each of the word lines WL1 to WLM based on the first to M-th row addresses RAD<1:M> after the start of the active operation during the arithmetic operation.

At time T4, the column control circuit 420 generates the first to N-th column signals YI<1:N> from the first to N-th input data DI<1:M>. In this example, the first to N-th input data DI<1:M> are generated to have a logic level combination that activates a plurality of columns (Plurality COL) among the columns 441-1 to 441-N.

The sense amplifier circuit 430 generates the internal voltage ILV by driving the segment line SIO based on the quantity of sense amplifiers 431-1 to 431-N that are activated based on one of the first to N-th internal data ID<1:N> stored in the sense amplifier circuit 430 and the first to N-th column signals YI<1:N>.

The analog to digital converter 451 of the arithmetic circuit 450 generates the first to J-th digital signals DIG<1:J> based on the voltage level of the internal voltage ILV.

The MAC operator 452 of the arithmetic circuit 450 generates the weight data WD by performing an arithmetic operation on the first to J-th digital signals DIG<1:J>. After performing the arithmetic operation, the MAC operator 452 outputs the weight data WD to the segment line SIO.

The time period from time T4 to time T5 is an arithmetic operation interval (MAC Operation) in which the internal voltage ILV is generated by driving the segment line SIO based on the quantity of sense amplifiers 431-1 to 431-N that are activated based on one of the first to N-th internal data ID<1:N> stored by the sense amplifier circuit 430 and the first to N-th column signals YI<1:N>, and a MAC operation is performed based on the voltage level of the internal voltage ILV.

At time T5, the command generation circuit 10 generates the word line activation command WEN enabled at a logic high level by decoding the first to L-th command addresses CA<1:L> after the start of the arithmetic operation.

The memory control circuit 20 generates the first to M-th row addresses RAD<1:M> and the first to N-th column addresses CAD<1:N> based on the first to L-th command addresses CA<1:L> when the word line activation command WEN is enabled. In this example, the first to M-th row addresses RAD<1:M> are generated to have a logic level combination that activates one word line (One WL) of the word lines WL1 to WLM. The first to N-th column addresses CAD<1:N> are generated to have a logic level combination that activates one column (One COL) among the columns 441-1 to 441-N.

The row control circuit 410 of the first mat 41 activates one of the word lines WL1 to WLM based on the first to M-th row addresses RAD<1:M> after the start of the active operation during the arithmetic operation.

The column control circuit 420 generates the first to N-th column signals YI<1:N> from the first to N-th column addresses CAD<1:M>.

One activated sense amplifier, among the sense amplifiers 431-1 to 431-N, amplifies the weight data WD loaded on the segment line SIO and stores the result as one of the first to N-th internal data ID<1:N> based on the first to N-th column signals YI<1:N>.

The period of time from time T5 to time T6 is an update operation interval (Update Operation) in which the weight data WD, generated after the start of an arithmetic operation, are stored in one of the columns 441-1 to 441-N.

At time T6, the command generation circuit 10 generates the pre-charge command PCG enabled at a logic high level by decoding the first to L-th command addresses CA<1:L> after the start of the arithmetic operation.

The sense amplifier control circuit 30 generates the pre-charge voltage VBLP at a voltage level that pre-charges the bit lines BL1 to BLN when the pre-charge command PCG is enabled.

The sense amplifier circuit 430 drives the first to N-th bit lines BL1 to BLN to the voltage level of the pre-charge voltage VBLP.

At time T7, the sense amplifier control circuit 30 generates the sense amplifier enable signal SAEN that is disabled at a logic low level based on the pre-charge command PCG that is generated at time T6.

As described, the semiconductor device 1 according to an embodiment of the present disclosure performs a MAC operation based on the internal data that are stored in the memory cell and the plurality of column signals that are input from outside of the semiconductor device 1 after the start of an arithmetic operation. After the start of an arithmetic operation, the semiconductor device 1 performs a MAC operation on the internal voltage generated based on the internal data stored in a memory cell and the plurality of input data output by another memory cell. The semiconductor device 1 may reduce current consumption by performing a MAC operation based on the internal data that are stored in the memory cell and the plurality of column signals without the input of data after the start of an arithmetic operation.

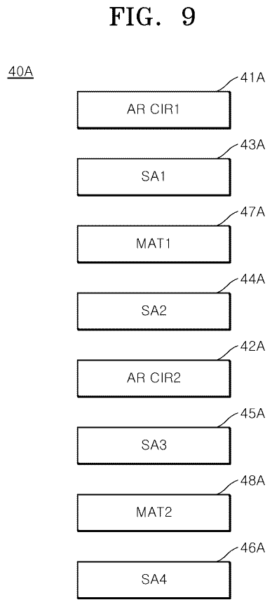

FIG. 9 is a block diagram illustrating a memory circuit 40A according to an embodiment of the present disclosure. The memory circuit 40A includes a first arithmetic circuit (AR CIR1) 41A, a second arithmetic circuit (AR CIR2) 42A, a first sense amplifier circuit (SA1) 43A, a second sense amplifier circuit (SA2) 44A, a third sense amplifier circuit (SA3) 45A, a fourth sense amplifier circuit (SA4) 46A, a first mat (MAT1) 47A, and a second mat (MAT2) 48A in the example of FIG. 9.

The first arithmetic circuit 41A is disposed on or over the first sense amplifier circuit 43A.

The first sense amplifier circuit 43A is disposed between the first arithmetic circuit 41A and the first mat 47A.

The first arithmetic circuit 41A is connected to the segment line SIO included in the first sense amplifier circuit 43A. The first arithmetic circuit 41A performs an arithmetic operation based on the internal data output by the first mat 47A and the voltage level of the internal voltage ILV generated as the segment line SIO is driven. The first arithmetic circuit 41A generates the weight data WD by performing an arithmetic operation on the internal voltage ILV. After performing the arithmetic operation, the first arithmetic circuit 41A outputs the weight data WD to the first sense amplifier circuit 43A.

The second sense amplifier circuit 44A is disposed between the first mat 47A and the second arithmetic circuit 42A.

The second sense amplifier circuit 44A inputs and outputs data by amplifying the data during normal operation performed on the first mat 47A.

The second arithmetic circuit 42A is disposed between the second sense amplifier circuit 44A and the third sense amplifier circuit 45A.

The third sense amplifier circuit 45A is disposed between the second arithmetic circuit 42A and the second mat 48A.

The second arithmetic circuit 42A is connected to the segment line SIO included in the third sense amplifier circuit 45A. The second arithmetic circuit 42A performs an arithmetic operation based on the internal data output by the second mat 48A and the voltage level of the internal voltage ILV generated as the segment line SIO is driven. The second arithmetic circuit 42A generates the weight data WD by performing an arithmetic operation on the internal voltage ILV. After performing the arithmetic operation, the second arithmetic circuit 42A outputs the weight data WD to the third sense amplifier circuit 45A.

The fourth sense amplifier circuit 46A is disposed below or under the second mat 48A.

The fourth sense amplifier circuit 46A inputs and outputs data by amplifying the data during normal operation performed on the second mat 48A.

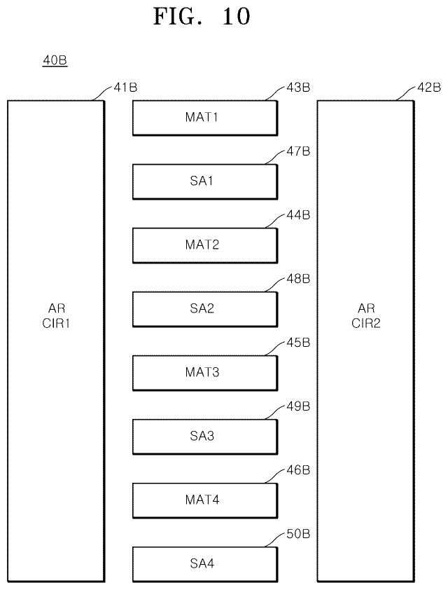

FIG. 10 is a block diagram illustrating a memory circuit 40B according to an embodiment of the present disclosure. The memory circuit 40B includes a first arithmetic circuit (AR CIR1) 41B, a second arithmetic circuit (AR CIR2) 42B, a first mat (MAT1) 43B, a second mat (MAT2) 44B, a third mat (MAT3) 45B, a fourth mat (MAT4) 46B, a first sense amplifier circuit (SA1) 47B, a second sense amplifier circuit (SA2) 48B, a third sense amplifier circuit (SA3) 49B, and a fourth sense amplifier circuit (SA4) 50B in the example of FIG. 10.

The first arithmetic circuit 41B is disposed on the left side of the first mat 43B, the second mat 44B, the third mat 45B, the fourth mat 46B, the first sense amplifier circuit 47B, the second sense amplifier circuit 48B, the third sense amplifier circuit 49B, and the fourth sense amplifier circuit 50B.

The first arithmetic circuit 41B is connected to the segment line SIO included in the first sense amplifier circuit 47B. The first arithmetic circuit 41B performs an arithmetic operation based on the internal data output by the first mat 43B and the voltage level of the internal voltage ILV generated as the segment line SIO is driven. The first arithmetic circuit 41B generates the weight data WD by performing an arithmetic operation on the internal voltage ILV. After performing the arithmetic operation, the first arithmetic circuit 41B outputs the weight data WD to the first sense amplifier circuit 47B.

The first arithmetic circuit 41B is connected to the segment line SIO included in the third sense amplifier circuit 49B. The first arithmetic circuit 41B performs an arithmetic operation, based on the internal data output by the third mat 45B and the voltage level of the internal voltage ILV generated as the segment line SIO is driven. The first arithmetic circuit 41B generates the weight data WD by performing an arithmetic operation on the internal voltage ILV. After performing the arithmetic operation, the first arithmetic circuit 41B outputs the weight data WD to the third sense amplifier circuit 49B.

The second arithmetic circuit 42B is disposed on the right side of the first mat 43B, the second mat 44B, the third mat 45B, the fourth mat 46B, the first sense amplifier circuit 47B, the second sense amplifier circuit 48B, the third sense amplifier circuit 49B, and the fourth sense amplifier circuit 50B.

The second arithmetic circuit 42B is connected to the segment line SIO included in the second sense amplifier circuit 48B. The second arithmetic circuit 42B performs an arithmetic operation based on the internal data output by the second mat 44B and the voltage level of the internal voltage ILV generated as the segment line SIO is driven. The second arithmetic circuit 42B generates the weight data WD by performing an arithmetic operation on the internal voltage ILV. After performing the arithmetic operation, the second arithmetic circuit 42B outputs the weight data WD to the second sense amplifier circuit 48B.

The second arithmetic circuit 42B is connected to the segment line SIO included in the fourth sense amplifier circuit 50B. The second arithmetic circuit 42B performs an arithmetic operation based on the internal data output by the fourth mat 46B and the voltage level of the internal voltage ILV generated as the segment line SIO is driven. The second arithmetic circuit 42B generates the weight data WD by performing an arithmetic operation on the internal voltage ILV. After performing the arithmetic operation, the second arithmetic circuit 42B outputs the weight data WD to the fourth sense amplifier circuit 50B.

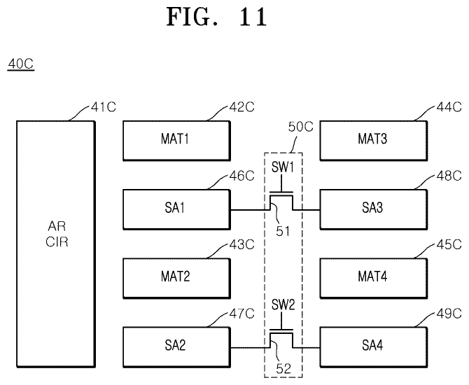

FIG. 11 is a block diagram illustrating a memory circuit 40C according to an embodiment of the present disclosure. The memory circuit 40C includes an arithmetic circuit (AR CIR) 41C, a first mat (MAT1) 42C, a second mat (MAT2) 43C, a third mat (MAT3) 44C, a fourth mat (MAT4) 45C, a first sense amplifier circuit (SA1) 46C, a second sense amplifier circuit (SA2) 47C, a third sense amplifier circuit (SA3) 48C, a fourth sense amplifier circuit (SA4) 49C, and a switch circuit 50C in the example of FIG. 11.

The arithmetic circuit 41C is disposed on the left side of the first mat 42C, the second mat 43C, the first sense amplifier circuit 46C, and the second sense amplifier circuit 47C.

The arithmetic circuit 41C may be connected to the segment line SIO included in the first sense amplifier circuit 46C. The arithmetic circuit 41C performs an arithmetic operation based on the internal data output by the first mat 42C and the voltage level of the internal voltage ILV generated as the segment line SIO is driven. The arithmetic circuit 41C generates the weight data WD by performing an arithmetic operation on the internal voltage ILV. After performing the arithmetic operation, the arithmetic circuit 41C outputs the weight data WD to the first sense amplifier circuit 46C.

The arithmetic circuit 41C is connected to the segment line SIO included in the second sense amplifier circuit 47C. The arithmetic circuit 41C performs an arithmetic operation based on the internal data output by the second mat 43C and the voltage level of the internal voltage ILV generated as the segment line SIO is driven. The arithmetic circuit 41C generates the weight data WD by performing an arithmetic operation on the internal voltage ILV. After performing the arithmetic operation, the arithmetic circuit 41C outputs the weight data WD to the second sense amplifier circuit 47C.

The third sense amplifier circuit 48C inputs and outputs data by amplifying the data during normal operation performed on the third mat 44C.

The fourth sense amplifier circuit 49C inputs and outputs data by amplifying the data during normal operation performed on the fourth mat 45C.

The switch circuit 50C is disposed between the first sense amplifier circuit 46C and the third sense amplifier circuit 48C and between the second sense amplifier circuit 47C and the fourth sense amplifier circuit 49C.

The switch circuit 50C includes a first switch 51 and a second switch 52, for example.

The first switch 51 connects the first sense amplifier circuit 46C and the third sense amplifier circuit 48C based on a first switch signal SW1 enabled at a logic high level after the start of an arithmetic operation. The first switch 51 blocks a connection between the first sense amplifier circuit 46C and the third sense amplifier circuit 48C based on the first switch signal SW1 disabled at a logic low level after the start of normal operation. The switch circuit 50C performs an arithmetic operation by connecting the first sense amplifier circuit 46C and the third sense amplifier circuit 48C after the start of the arithmetic operation. The switch circuit 50C may prevent operation error of normal operation by blocking a connection between the first sense amplifier circuit 46C and the third sense amplifier circuit 48C after the start of normal operation.

The second switch 52 connects the second sense amplifier circuit 47C and the fourth sense amplifier circuit 49C based on the second switch signal SW2 enabled at a logic high level after the start of an arithmetic operation. The second switch 52 blocks a connection between the second sense amplifier circuit 47C and the fourth sense amplifier circuit 49C based on the second switch signal SW2 disabled at a logic low level after the start of normal operation. The switch circuit 50C may perform an arithmetic operation by connecting the second sense amplifier circuit 47C and the fourth sense amplifier circuit 49C after the start of the arithmetic operation. The switch circuit 50C may prevent operation error during normal operation by blocking a connection between the second sense amplifier circuit 47C and the fourth sense amplifier circuit 49C after the start of normal operation.

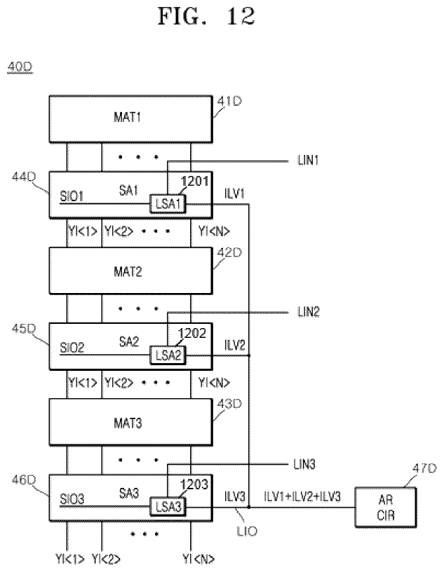

FIG. 12 is a block diagram illustrating a memory circuit 40D according to an embodiment of the present disclosure. The memory circuit 40D includes a first mat (MAT1) 41D, a second mat (MAT2) 42D, a third mat (MAT3) 43D, a first sense amplifier circuit (SA1) 44D, a second sense amplifier circuit (SA1) 45D, a third sense amplifier circuit (SA1) 46D, and an arithmetic circuit (AR CIR) 47D.

The first mat 41D is disposed on or over the first sense amplifier circuit 44D.

The first sense amplifier circuit 44D is disposed between the first mat 41D and the second mat 42D.

The first sense amplifier circuit 44D includes a first local sense amplifier (LSA1) 1201, for example. The first local sense amplifier 1201 connects a first segment line SIO1 and a local line LIO when a first local input signal LIN1 is enabled. The first sense amplifier circuit 44D may output, to the local line LIO, internal data that are output based on a plurality of column signals YI<1:N> in the first mat 41D and a first internal voltage ILV1 that is generated as the first segment line SIO1 is driven.

The second mat 42D is disposed between the first sense amplifier circuit 44D and the second sense amplifier circuit 45D.

The second sense amplifier circuit 45D is disposed between the second mat 42D and the third mat 43D.

The second sense amplifier circuit 45D includes a second local sense amplifier (LSA2) 1202, for example. The second local sense amplifier 1202 connects a second segment line SIO2 and the local line LIO when a second local input signal LIN2 is enabled. The second sense amplifier circuit 45D outputs, to the local line LIO, internal data output based on the plurality of column signals YI<1:N> in the second mat 42D and a second internal voltage ILV2 generated as the second segment line SIO2 is driven.

The third mat 43D is disposed between the second sense amplifier circuit 45D and the third sense amplifier circuit 46D.

The third sense amplifier circuit 46D is disposed below or under the third mat 43D.

The third sense amplifier circuit 46D includes a third local sense amplifier (LSA3) 1203. The third local sense amplifier 1203 connects a third segment line SIO3 and the local line LIO when a third local input signal LIN3 is enabled. The third sense amplifier circuit 46D outputs, to the local line LIO, internal data output based on the plurality of column signals YI<1:N> in the third mat 43D and a third internal voltage ILV3 generated as the third segment line SIO3 is driven.

The arithmetic circuit 47D is disposed, for example, to the side of the first mat 41D, the second mat 42D, the third mat 43D, the first sense amplifier circuit 44D, the second sense amplifier circuit 45D, and the third sense amplifier circuit 46D.

The arithmetic circuit 47D is connected to the local line LIO. The arithmetic circuit 47D performs an arithmetic operation based on the voltage level of the local line LIO, which is driven as the sum of the first internal voltage ILV1 output by the first sense amplifier circuit 44D, the second internal voltage ILV2 output by the second sense amplifier circuit 45D, and the third internal voltage ILV3 output by the third sense amplifier circuit 45D. The arithmetic circuit 47D generates the weight data WD by performing an arithmetic operation on the voltage level of the sum of the first internal voltage ILV1, the second internal voltage ILV2, and the third internal voltage ILV3. After performing the arithmetic operation, the arithmetic circuit 47D outputs the weight data WD to the first sense amplifier circuit 44D, the second sense amplifier circuit 445D, and the third sense amplifier circuit 46D.

An arithmetic operation of the memory circuit 40D illustrated in FIG. 12 according to a first embodiment is described.

The memory circuit 40D performs an arithmetic operation based on the internal data of one of the first mat 41D, the second mat 42D, and the third mat 43D, output based on the plurality of column signals YI<1:N > and the voltage level of the local line LIO driven based on the first local input signal LIN1, the second local input signal LIN2, and the third local input signal LIN3.

The memory circuit 40D according to a first embodiment performs a MAC operation after the start of an arithmetic operation, based on the internal data of one of the first mat 41D, the second mat 42D, and the third mat 43D and the voltage level of the local line LIO driven based on the first local input signal LIN1, the second local input signal LIN2, and the third local input signal LIN3 input from outside the memory circuit 40D. The memory circuit 40D performs a MAC operation on the internal data of one of the first mat 41D, the second mat 42D, and the third mat 43D and the voltage level of the sum of the first internal voltage ILV1, the second internal voltage ILV2, and the third internal voltage ILV3 generated based on the first local input signal LIN1, the second local input signal LIN2, and the third local input signal LIN3 input from outside the memory circuit 40D, after the start of an arithmetic operation. The memory circuit 40D may reduce current consumption by performing a MAC operation, without input of data after the start of an arithmetic operation, on the internal data of one of the first mat 41D, the second mat 42D, and the third mat 43D and the voltage level of the sum of the first internal voltage ILV1, the second internal voltage ILV2, and the third internal voltage ILV3 generated based on the first local input signal LIN1, the second local input signal LIN2, and the third local input signal LIN3 input from outside the memory circuit 40D.

An arithmetic operation of the memory circuit 40D illustrated in FIG. 12 according to an embodiment is described.

The memory circuit 40D performs an arithmetic operation based on a plurality of internal data of the first mat 41D, the second mat 42D, and the third mat 43D, output based on the plurality of column signals YI<1:N>, and the voltage level of the local line LIO driven based on the first local input signal LIN1, the second local input signal LIN2, and the third local input signal LIN3.

The memory circuit 40D according to an embodiment performs, after the start of an arithmetic operation, a MAC operation based on the plurality of internal data generated by the first mat 41D, the second mat 42D, and the third mat 43D and the voltage level of the local line LIO driven based on the first local input signal LIN1, the second local input signal LIN2, and the third local input signal LIN3 input from outside the memory circuit 40D. The memory circuit 40D performs a MAC operation after the start of an arithmetic operation on the plurality of internal data generated by the first mat 41D, the second mat 42D, and the third mat 43D and the voltage level of the sum of the first internal voltage ILV1, the second internal voltage ILV2, and the third internal voltage ILV3 generated based on the first local input signal LIN1, the second local input signal LIN2, and the third local input signal LIN3 input from the outside of the memory circuit 40D. The memory circuit 40D may reduce current consumption by performing a MAC operation, without the input of data after the start of an arithmetic operation, on the plurality of internal data generated by the first mat 41D, the second mat 42D, the third mat 43D and the voltage level of the sum of the first internal voltage ILV1, the second internal voltage ILV2, and the third internal voltage ILV3 generated based on the first local input signal LIN1, the second local input signal LIN2, and the third local input signal LIN3 input from outside the memory circuit 40D.

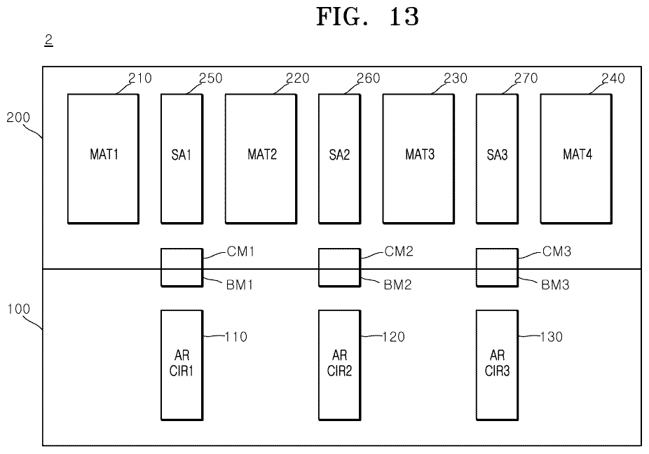

FIG. 13 is a block diagram illustrating an embodiment of a semiconductor device 2 according to the present disclosure. As illustrated in FIG. 13, the semiconductor device 20 includes a base chip 100 and a core chip 200.

The base chip 100 includes a first arithmetic circuit (AR CIR1) 110, a second arithmetic circuit (AR CIR2) 120, a third arithmetic circuit (AR CIR3) 130, first base conductor BM1, second base conductor BM2, and third base conductor BM3.

The core chip 200 includes a first mat (MAT1) 210, a second mat (MAT2) 220, a third mat (MAT3) 230, a fourth mat (MAT4) 240, a first sense amplifier circuit (SA1) 250, a second sense amplifier circuit (SA2) 260, a third sense amplifier circuit (SA3) 270, first core conductor CM1, second core conductor CM2, and third core conductor CM3.

The first base conductor BM1, second base conductor BM2, and third base conductor BM3 of the base chip 100 are electrically connected to the first core conductor CM1, second core conductor CM2, and third core conductor CM3 of the core chip 200, respectively. The base chip 100 and the core chip 200 may be connected by hybrid bonding by which pieces of metal or electrical conductors are directly connected or a plurality of bumps.

The first sense amplifier circuit 250 of the core chip 200 is electrically connected to the first core conductor CM1. The first sense amplifier circuit 250 amplifies and stores internal data output by the first mat 210 after the start of an arithmetic operation. The first sense amplifier circuit 250 generates the internal voltage ILV by driving the segment line SIO based on the stored internal data and the plurality of column signals. The first sense amplifier circuit 250 stores, in the first mat 210, the weight data WD input through the first core conductor CM1.

The second sense amplifier circuit 260 of the core chip 200 is electrically connected to the second core conductor CM2. The second sense amplifier circuit 260 amplifies and stores internal data output by the second mat 220 after the start of an arithmetic operation. The second sense amplifier circuit 260 generates the internal voltage ILV by driving the segment line SIO based on the stored internal data and the plurality of column signals. The second sense amplifier circuit 260 may store, in the second mat 220, the weight data WD input through the second core conductor CM2.

The third sense amplifier circuit 270 of the core chip 200 is electrically connected to the third core conductor CM3. The third sense amplifier circuit 270 amplifies and stores internal data output by the third mat 230 after the start of an arithmetic operation. The third sense amplifier circuit 270 generates the internal voltage ILV by driving the segment line SIO based on the stored internal data and the plurality of column signals. The third sense amplifier circuit 270 stores, in the third mat 230, the weight data WD input through the third core conductor CM3.

The first arithmetic circuit 110 of the base chip 100 is electrically connected to the first base conductor BM1. The first arithmetic circuit 110 performs an arithmetic operation on the internal voltage ILV output by the first sense amplifier circuit 250 included in the core chip 200. After performing the arithmetic operation, the first arithmetic circuit 110 outputs the weight data WD to the first sense amplifier circuit 250 included in the core chip 200 through the first base conductor BM1.

The second arithmetic circuit 120 of the base chip 100 is electrically connected to the second base conductor BM2. The second arithmetic circuit 120 performs an arithmetic operation on the internal voltage ILV output by the second sense amplifier circuit 260 included in the core chip 200. After performing the arithmetic operation, the second arithmetic circuit 120 outputs the weight data WD to the second sense amplifier circuit 260 included in the core chip 200 through the second base conductor BM2.

The third arithmetic circuit 130 of the base chip 100 is electrically connected to the third base conductor BM3. The third arithmetic circuit 130 performs an arithmetic operation on the internal voltage ILV output by the third sense amplifier circuit 270 included in the core chip 200. After performing the arithmetic operation, the third arithmetic circuit 130 outputs the weight data WD to the third sense amplifier circuit 270 included in the core chip 200 through the third base conductor BM3.

After the start of an arithmetic operation, the semiconductor device 2 performs a MAC operation based on the voltage level of the segment line SIO driven based on a plurality of internal data generated by the core chip 200 and the plurality of column signals. After the start of an arithmetic operation, the semiconductor device 2 performs a MAC operation on the voltage levels of the plurality of internal voltages ILV generated based on the plurality of internal data generated by the core chip 200 and the plurality of column signals. The semiconductor device 2 may reduce current consumption by performing a MAC operation, without the input of data, on the voltage levels of the plurality of internal voltages ILV generated based on the plurality of internal data generated by the core chip 200 and the plurality of column signals after the start of an arithmetic operation.

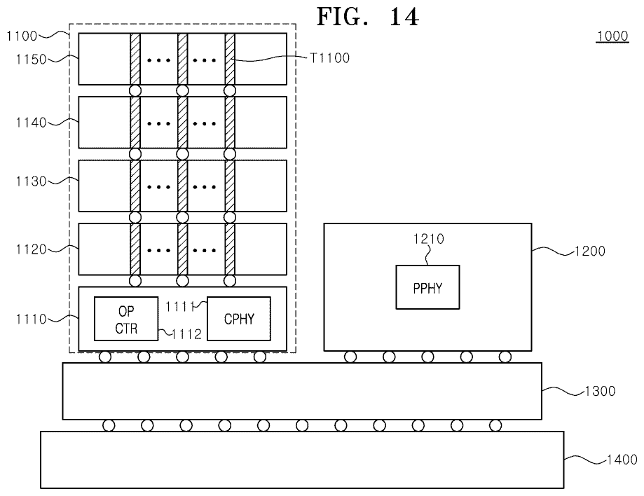

FIG. 14 is a block diagram illustrating a stack memory system 1000 according to an example of the present disclosure. As illustrated in FIG. 14, the stack memory system 1000 includes a semiconductor device 1100, a processor 1200, an interposer 1300, and a substrate 1400.

The interposer 1300 is formed on or over the substrate 1400. The semiconductor device 1100 and the processor 1200 is formed on or over the interposer 1300. The interposer 1300 electrically connects the substrate 1400, the semiconductor device 1100, and the processor 1200. The substrate 1400, the semiconductor device 1100, and the processor 1200 may be electrically connected by using the interposer 1300 including wires of varied form when a difference between the pitches of the substrate 1400, the semiconductor device 1100, and the processor 1200 is large.

The processor 1200 includes a processor interface circuit (PPHY) 1210. The processor 1200 conveys signals, including a chip ID, a command, and an address that controls various internal operations of the semiconductor device 1100, to the semiconductor device 1100 through the processor interface circuit 1210 and receives data from the semiconductor device 1100 through the processor interface circuit 1210.

The semiconductor device 1100 includes a base chip 1110 and core chips 1120, 1130, 1140, and 1150. The semiconductor device 1100 is implemented according to the semiconductor device 1 illustrated in FIG. 1 or the semiconductor device 2 illustrated in FIG. 13. The mats of the semiconductor device 1100 are implemented in accord with FIG. 4.

The core chips 1120, 1130, 1140, and 1150 are sequentially stacked on or over the base chip 1110 and receive various signals from the base chip 1110 via through electrodes T1100.

The base chip 1110 includes a core interface circuit (CPHY) 1111 and an operation control circuit (OP CTR) 1112. The core interface circuit 1111 is configured to communicate with the processor interface circuit 1112 and transfers signals, including a chip ID, a command, and an address transmitted by the processor 1200, to the operation control circuit 1112 and conveys data generated by the operation control circuit 1112 to the processor 1200. The core interface circuit 1111 are implemented with the command generation circuit 10 and the memory control circuit 20 illustrated in FIG. 1. The operation control circuit 1112 is implemented with the sense amplifier control circuit 30, the memory circuit 40, and the data I/O circuit 50 illustrated in FIG. 1.

The semiconductor device 1100 performs a MAC operation based on internal data stored in a memory cell and a plurality of column signals input from outside the semiconductor device 1100 after the start of an arithmetic operation. The semiconductor device 1100 performs a MAC operation on an internal voltage generated based on internal data stored in a memory cell and a plurality of input data output by another memory cell after the start of an arithmetic operation. The semiconductor device 1100 can reduce current consumption by performing a MAC operation based on internal data stored in a memory cell and a plurality of column signals, without the input of data after the start of an arithmetic operation.

Concepts are disclosed in conjunction with examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above descriptions. All changes within the meaning and range of equivalency of the claims are included within their scope.

What is claimed is:

1. A semiconductor device comprising:
a sense amplifier circuit comprising a plurality of sense amplifiers connected to a plurality of columns, wherein the plurality of sense amplifiers stores internal data output by the plurality of columns by amplifying the internal data and generates an internal voltage by driving a segment line based on the internal data and a plurality of column signals after a start of an arithmetic operation; and
an arithmetic circuit configured to generate weight data by performing a multiply-accumulate (MAC) operation based on a voltage level of the internal voltage and configured to output the weight data to the segment line.

2. The semiconductor device of claim 1,
wherein each of the plurality of columns comprises a plurality of memory cells connected to a plurality of word lines and a plurality of bit lines, and
wherein each of the plurality of memory cells is implemented as a volatile memory cell.

3. The semiconductor device of claim 1, wherein the sense amplifier circuit generates the internal voltage having a voltage level based on a quantity of the plurality of sense amplifiers that are activated based on the internal data and the plurality of column signals.

4. The semiconductor device of claim 1, wherein the sense amplifier circuit stores the weight data in the plurality of columns through a sense amplifier activated among the plurality of sense amplifiers.

5. The semiconductor device of claim 1, wherein the arithmetic circuit comprises:
an analog to digital converter configured to generate a plurality of digital signals based on the voltage level of the internal voltage; and
a MAC operator configured to generate the weight data by performing a MAC operation on the plurality of digital signals and configured to output the weight data to the segment line.

6. The semiconductor device of claim 1, wherein the plurality of columns, the sense amplifier circuit, and the arithmetic circuit are included in a first mat.

7. The semiconductor device of claim 1, further comprising:
a row control circuit configured to activate one of a plurality of word lines connected to the plurality of columns based on a plurality of row addresses; and
a column control circuit configured to generate the plurality of column signals based on one of a plurality of column addresses and a plurality of input data.

8. The semiconductor device of claim 7, wherein the column control circuit:
generates the plurality of column signals based on the plurality of column addresses when a selection signal is disabled after the start of an active operation; and
generates the plurality of column signals based on the plurality of input data when the selection signal is enabled after the start of the arithmetic operation.

9. The semiconductor device of claim 7, wherein the plurality of input data comprises a signal input from a second mat.

10. The semiconductor device of claim 7, wherein the plurality of input data comprises a signal input from outside the semiconductor device.

11. A semiconductor device comprising:
a memory control circuit configured to generate a plurality of row addresses and a plurality of column addresses after a start of an active operation; and
a memory circuit configured to output internal data from one of a plurality of columns based on the plurality of row addresses and the plurality of column addresses after the start of the active operation, configured to generate weight data by performing a multiply-accumulate (MAC) operation based on a plurality of input data and the internal data after a start of an arithmetic operation, and configured to store the weight data as the internal data.

12. The semiconductor device of claim 11, wherein the memory circuit comprises:
a first mat configured to output the internal data from one of the plurality of columns based on the plurality of row addresses and the plurality of column addresses, configured to generate an internal voltage having a voltage level based on the plurality of input data and the internal data after the start of the arithmetic operation, configured to generate the weight data by performing the arithmetic operation based on the internal voltage, and configured to store the weight data as the internal data; and
a second mat configured to generate the plurality of input data by outputting a plurality of output data to a global line after the start of the arithmetic operation.

13. The semiconductor device of claim 12, wherein the first mat comprises:
a row control circuit configured to activate one of a plurality of word lines connected to the plurality of columns, based on the plurality of row addresses;
a column control circuit configured to generate a plurality of column signals based on one of the plurality of column addresses and the plurality of input data;
a sense amplifier circuit comprising a plurality of sense amplifiers connected to the plurality of columns, wherein the plurality of sense amplifiers stores the internal data that are output from the plurality of columns by amplifying the internal data after the start of the active operation, and generates the internal voltage by driving a segment line based on the internal data and the plurality of column signals after the start of the arithmetic operation; and
an arithmetic circuit configured to generate the weight data by performing the MAC operation based on the voltage level of the internal voltage and configured to output the weight data to the segment line.

14. The semiconductor device of claim 13:
wherein each of the plurality of columns comprises a plurality of memory cells connected to the plurality of word lines and a plurality of bit lines; and
wherein each of the plurality of memory cells is implemented as a volatile memory cell.

15. The semiconductor device of claim 13, wherein the column control circuit:
generates the plurality of column signals based on the plurality of column addresses when a selection signal is disabled after the start of an active operation; and
generates the plurality of column signals based on the plurality of input data when the selection signal is enabled after the start of the arithmetic operation.

16. The semiconductor device of claim 13, wherein the sense amplifier circuit generates the internal voltage having the voltage level based on a quantity of the plurality of sense amplifiers activated based on the internal data and the plurality of column signals.

17. The semiconductor device of claim 13, wherein the sense amplifier circuit stores the weight data in the plurality of columns through a sense amplifier activated among the plurality of sense amplifiers.

18. The semiconductor device of claim 13, wherein the arithmetic circuit comprises:
an analog to digital converter configured to generate a plurality of digital signals based on the voltage level of the internal voltage; and
a MAC operator configured to generate the weight data by performing a MAC operation on the plurality of digital signals and configured to output the weight data to the segment line.

19. A semiconductor device comprising:
a memory control circuit configured to generate a plurality of row addresses and a plurality of column addresses after a start of an active operation; and
a memory circuit configured to activate one of a plurality of word lines based on the plurality of row addresses and the plurality of column addresses after the start of the active operation, configured to output internal data from a memory cell connected to the activated word line, configured to deactivate the plurality of word lines after a start of an arithmetic operation, and configured to perform a multiply-accumulate (MAC) operation based on a plurality of input data and the internal data.

20. The semiconductor device of claim 19, wherein the memory circuit comprises:
a first mat configured to activate one of the plurality of word lines based on the plurality of row addresses, configured to output the internal data from a memory cell connected to the activated word line based on the plurality of column addresses, configured to deactivate the plurality of word lines after the start of the arithmetic operation, configured to generate an internal voltage having a voltage level based on a plurality of input data and the internal data, configured to generate weight data by performing the MAC operation based on the internal voltage, and configured to store the weight data as the internal data; and
a second mat configured to generate the plurality of input data by outputting a plurality of output data to a global line after the start of the arithmetic operation.

21. The semiconductor device of claim 20, wherein the first mat comprises:
a row control circuit configured to activate one of the plurality of word lines connected to the plurality of columns based on the plurality of row addresses after the start of the active operation and configured to deactivate the plurality of word lines after the start of the arithmetic operation;
a column control circuit configured to generate a plurality of column signals based on one of the plurality of column addresses and the plurality of input data;
a sense amplifier circuit comprising a plurality of sense amplifiers connected to the plurality of columns, wherein the plurality of sense amplifiers stores the internal data that are output by the plurality of columns by amplifying the internal data after the start of the active operation and generates the internal voltage by driving a segment line based on the internal data and the plurality of column signals after the start of the arithmetic operation; and
an arithmetic circuit configured to perform the MAC operation based on the voltage level of the internal voltage.

22. The semiconductor device of claim 21:
wherein each of the plurality of columns comprises a plurality of memory cells connected to the plurality of word lines and a plurality of bit lines; and
wherein each of the plurality of memory cells is implemented as a volatile memory cell.

23. The semiconductor device of claim 21, wherein the column control circuit:
generates the plurality of column signals based on the plurality of column addresses when a selection signal is disabled after the start of the active operation, and
generates the plurality of column signals based on the plurality of input data when the selection signal is enabled after the start of the arithmetic operation.

24. The semiconductor device of claim 21, wherein the sense amplifier circuit generates the internal voltage having the voltage level based on a quantity of the plurality of sense amplifiers activated based on the internal data and the plurality of column signals.

25. The semiconductor device of claim 21, wherein the arithmetic circuit comprises:
an analog to digital converter configured to generate a plurality of digital signals based on the voltage level of the internal voltage; and
a MAC operator configured to generate the weight data by performing the MAC operation on the plurality of digital signals.

26. A semiconductor device comprising:
a memory control circuit configured to generate a plurality of row addresses and a plurality of column addresses; and
a memory circuit comprising a memory cell and a plurality of word lines including a first word line connected to the memory cell and configured to activate the first word line based on the plurality of row addresses and the plurality of column addresses and output internal data from the memory cell, configured to deactivate the plurality of word lines subsequent to beginning an arithmetic operation, and further comprising a multiply-accumulate (MAC) operator that performs a MAC operation based on input data and the internal data.
